(19) United States
(12) Patent Application Publication
(10) Pub. No.: US 2025/0226286 A1
(43) Pub. Date: Jul. 10, 2025

(54) HEAT DISSIPATION BASE, SEMICONDUCTOR MODULE, AND ENERGY CONVERSION DEVICE

(71) Applicant: FUJI ELECTRIC CO., LTD., Kawasaki-shi (JP)

(72) Inventors: Ryo NOMAGUCHI, Kawasaki-shi (JP); Masaoki MIYAKOSHI, Kawasaki-shi (JP)

(73) Assignee: FUJI ELECTRIC CO., LTD., Kawasaki-shi (JP)

(21) Appl. No.: 19/092,168

(22) Filed: Mar. 27, 2025

Related U.S. Application Data
(63) Continuation of application No. PCT/JP2024/003211, filed on Feb. 1, 2024.

(30) Foreign Application Priority Data
Mar. 13, 2023 (JP) 2023-038214

(51) Int. Cl. H01L 23/40; H01L 23/498

(52) U.S. Cl. CPC H01L 23/4006; H01L 23/498

(57) ABSTRACT

A heat dissipation base, having: a first surface configured to have a wiring board bonded thereto; and a second surface that is a convex curved surface and has a substantially rectangular shape, which has two neighboring sides extending respectively in a first direction and a second direction, in a plan view of the heat dissipation base. The second surface is opposite to the first surface, and is so shaped that, when the second surface faces downward, the second surface forms a first curve and a second curve, which are a first downward convex curve and a second downward convex curve, respectively, in first and second cross-sectional views. The second surface forms a third curve having an inflection point, first and second parts of the third curve, respectively further outward and inward than the infection point, forming an upward convex curve and another downward convex curve, in a third cross-sectional view.

This is a continuation application of International Application PCT/JP2024/003211 filed on Feb. 1, 2024 which claims priority from a Japanese Patent Application No. 2023-038214 filed on Mar. 13, 2023, the contents of which are incorporated herein by reference.

### TECHNICAL FIELD

The present invention relates to a heat dissipation base, a semiconductor module, and an energy conversion device.

### BACKGROUND ART

Examples of a semiconductor device used for a power conversion device such as an inverter device include one in which a heat dissipation base with a wiring board, a semiconductor element, and the like arranged is attached to a cooler. Examples of a heat dissipation base used for this type of semiconductor device include one in which a second surface that is to face a cooler and is opposite to a first surface on which a wiring board, a semiconductor element, and the like are arranged is molded to have a convex shape (e.g., refer to Patent Literatures 1 to 7).

### CITATION LIST

### Patent Literature

Patent Literature 1: JP 2018-195717 A

Patent Literature 2: JP 2020-188152 A

Patent Literature 3: JP 2016-167548 A

Patent Literature 4: WO 2012/108073 A

Patent Literature 5: JP 2007-88045 A

Patent Literature 6: JP 2005-39081 A

Patent Literature 7: U.S. Pat. No. 7,511,961

### SUMMARY OF INVENTION

### Technical Problem

A wiring board is bonded to a first surface of a heat dissipation base with a bonding material. When the heat dissipation base molded to have a convex second surface is attached to a cooler, the second surface deforms in a direction in which the convex curved surface changes to a flat surface. Accordingly, the deformation of the heat dissipation base applies a deformation stress to the wiring board bonded to the first surface of the heat dissipation base with the bonding material, which sometimes damages the wiring board.

In one aspect, an object of the present invention is to prevent damage to a wiring board caused by deformation of a heat dissipation base to which the wiring board is bonded.

### Solution to Problem

A heat dissipation base according to one aspect is a heat dissipation base including a first surface to which a wiring board is to be bonded; and a second surface which is opposite to the first surface and is to face a cooler, in which the second surface of the heat dissipation base is a convex curved surface and has a substantially rectangular shape in plan view having a side extending in a first direction and a side extending in a second direction, and when the second surface faces downward, in each of a first curve representing a shape of the second surface on a first straight line passing through a center of the second surface and extending in the first direction, and a second curve representing a shape of the second surface on a second straight line passing through the center of the second surface and extending in the second direction, a change in a shape in a direction from an end to the center including the end is represented by a downward convex curve, and in a third curve representing a shape of the second surface on a straight line in a diagonal direction of the heat dissipation base, a change in a shape in a direction from an end to the center including the end is represented by an upward convex curve, and a change in a shape in a direction from the center to the end including the center is represented by a downward convex curve.

### Advantageous Effects of Invention

According to the above aspect, it is possible to prevent damage to a wiring board caused by deformation of a heat dissipation base to which the wiring board is bonded.

### BRIEF DESCRIPTION OF DRAWINGS

FIG. 1 is a top view illustrating a configuration example of an energy conversion device according to an embodiment.

FIG. 2 is a cross-sectional side view illustrating a configuration example of the interior of the energy conversion device taken along an A-A′ line in FIG. 1.

FIG. 3 is a cross-sectional side view of the energy conversion device taken along a B-B′ line in FIG. 1.

FIG. 4 is a diagram illustrating a configuration example of a circuit of a semiconductor module.

FIG. 5 is a bottom view illustrating an example of a coating pattern of a heat conductive material when a heat dissipation base is attached to a cooler.

FIGS. 6A to 6C are diagrams illustrating how a heat conductive material spreads when a heat dissipation base is attached to a cooler.

FIG. 7 is a diagram illustrating an example of a problem that occurs when a heat dissipation base is attached to a cooler.

FIG. 8 is a top view illustrating an example of a shape of a heat dissipation base according to the embodiment.

FIG. 9 is a graph illustrating the tendency of warpage in three directions in the heat dissipation base illustrated in FIG. 8.

FIG. 10 is a graph illustrating a specific example of warpage in the diagonal direction in the heat dissipation base illustrated in FIG. 8.

FIG. 11 is a diagram illustrating deformation of the heat dissipation base illustrated in FIG. 8 when the heat dissipation base is attached to the cooler.

FIG. 12 is a supplementary diagram for a shape of a convex curved surface in the heat dissipation base according to the embodiment.

### DESCRIPTION OF EMBODIMENTS

Hereinafter, an embodiment of the present invention will be described in detail with reference to the drawings. Note that each of X, Y, and Z axes in each drawing to be referred is indicated to define a plane or a direction in an energy conversion device, a semiconductor module, or the like to be illustrated. The X, Y, and Z axes are orthogonal to each other and form a right-handed system. In the following description, the Z direction may be referred to as a vertical direction. In addition, a plane including the X axis and the Y axis may be referred to as an XY plane, a plane including the Y axis and the Z axis may be referred to as a YZ plane, and a plane including the Z axis and the X axis may be referred to as a ZX plane. Such directions and planes are terms used for convenience of description. Thus, depending on the attachment posture of the energy conversion device or the like, the correspondence relationship with the X, Y, and Z directions may vary. For example, in the present specification, a surface facing a Z direction positive side (+Z direction) in a member forming the energy conversion device is referred to as a top surface, and a surface facing a Z direction negative side (−Z direction) is referred to as a bottom surface. However, the surface facing the Z direction negative side may be referred to as the top surface, and the surface facing the Z direction positive side may be referred to as the bottom surface. Further, in the present specification, the term “in plan view” means a case where the top surface or the bottom surface (XY plane) of the energy conversion device or the like is viewed from the Z direction.

An aspect ratio and a size relationship between the members in each drawing are merely schematically represented, and do not necessarily coincide with a relationship in an energy conversion device or the like actually manufactured. For convenience of description, it is also assumed that the size relationship between the members might be exaggerated. In addition, the shapes of the same members may be different between different drawings.

In the following description, as an example of an energy conversion device according to the present disclosure, a device applied to a power conversion device such as an inverter device of an industrial or in-vehicle motor is exemplified. Thus, in the following description, detailed description of the same or similar configuration, function, operation, assembly method, or the like as those of a known energy conversion device will be omitted.

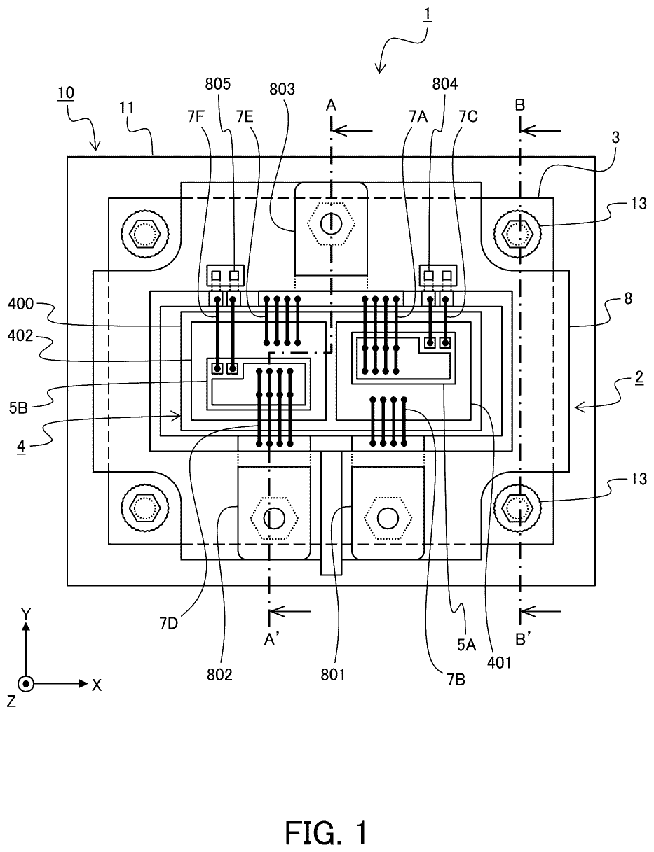

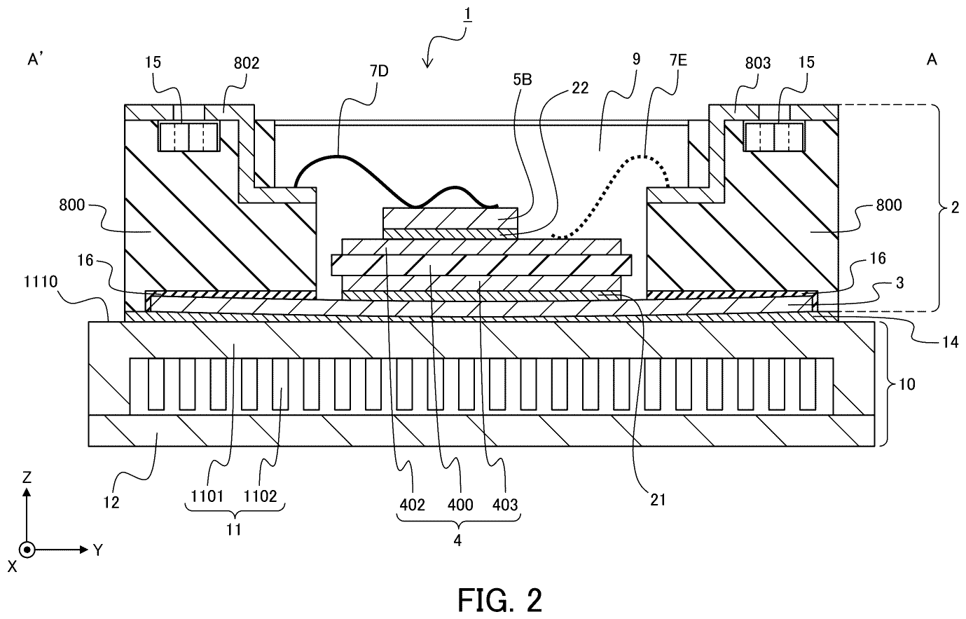

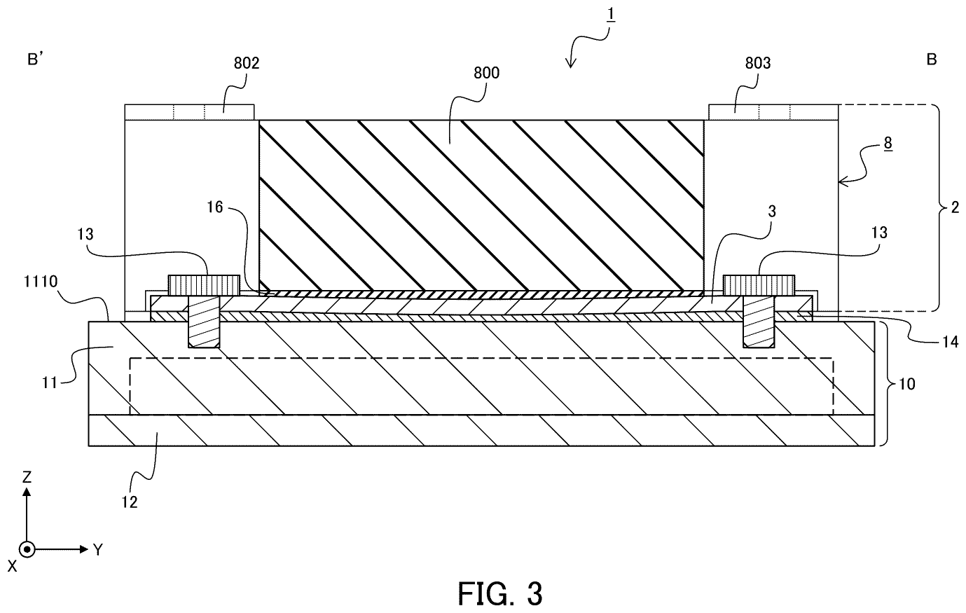

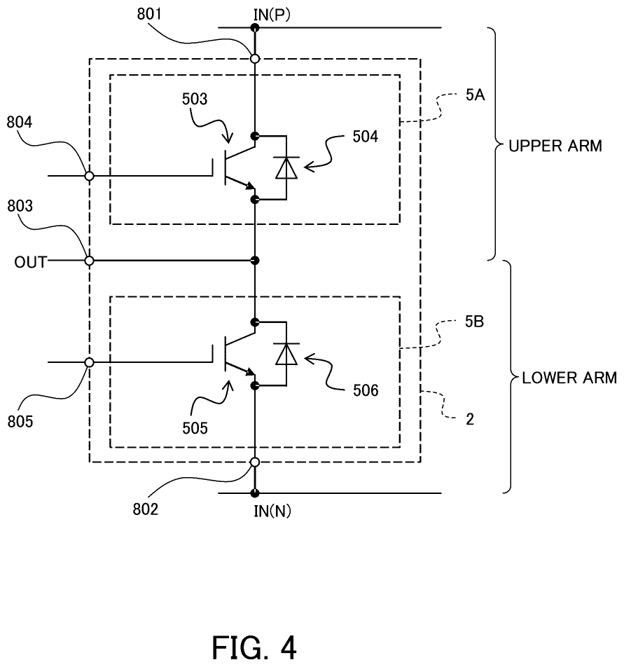

FIG. 1 is a top view illustrating a configuration example of an energy conversion device according to an embodiment. FIG. 2 is a cross-sectional side view illustrating a configuration example of the interior of the energy conversion device taken along an A-A′ line in FIG. 1. FIG. 3 is a cross-sectional side view of the energy conversion device taken along a B-B′ line in FIG. 1. FIG. 4 is a diagram illustrating a configuration example of a circuit of a semiconductor module. Note that, in FIG. 1, a sealing material that seals a wiring board, a semiconductor element, or the like is omitted. FIG. 2 schematically illustrates a configuration example of a portion of the energy conversion device taken along the A-A′ line in FIG. 1 on the left side with the A-A′ line as a boundary, when viewed from the right. In FIG. 2, hatching indicating a cross section of the sealing material is omitted. FIG. 3 schematically illustrates a configuration example of a portion of the energy conversion device taken along the B-B′ line in FIG. 1 on the left side with the B-B′ line as a boundary, when viewed from the right.

An energy conversion device 1 illustrated in FIGS. 1 to 3 includes a semiconductor module 2 as a semiconductor device and a cooler 10. The semiconductor module 2 includes a heat dissipation base 3, a wiring board 4, semiconductor elements 5A and 5B, a plurality of bonding wires 7A to 7F, a case 8, and a sealing material 9. The cooler 10 includes a fin 11 and a water jacket 12. The semiconductor module 2 is inserted into a through hole of the heat dissipation base 3, and is attached to the cooler 10 with a screw 13 having a male screw to be screwed into a screw hole (female screw) provided on a top surface 1110 of the fin 11 of the cooler 10. The heat dissipation base 3 of the semiconductor module 2 and the fin 11 of the cooler 10 are connected via a heat conductive material 14 such as thermal grease or thermal compound.

The semiconductor module 2 illustrated in FIGS. 1 to 3 forms a single-phase voltage type half-bridge inverter circuit as illustrated in FIG. 4. The wiring board 4 is disposed on the top surface of the heat dissipation base 3 of this type of semiconductor module 2. The wiring board 4 includes an insulating substrate 400, a first conductor pattern 401 and a second conductor pattern 402 provided on a top surface (first surface) of the insulating substrate 400, and a third conductor pattern 403 provided on a bottom surface (second surface) of the insulating substrate 400. The wiring board 4 may be, for example, a direct copper bonding (DCB) substrate or an active metal brazing (AMB) substrate. The wiring board 4 may be referred to as a laminated substrate or an insulating circuit substrate.

The insulating substrate 400 is not limited to a specific substrate. The insulating substrate 400 may be, for example, a ceramic substrate including a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 400 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The third conductor pattern 403 is a member that functions as a heat conducting member for conducting heat generated in the inverter circuit to the heat dissipation base 3 and is formed of, for example, a metal plate, a metal foil, or the like of copper, aluminum, or the like. The third conductor pattern 403 is bonded to the heat dissipation base 3 with a bonding material 21 such as solder. The third conductor pattern 403 may be referred to as a heat dissipation layer or a heat dissipation pattern.

The first conductor pattern 401 and the second conductor pattern 402 are members that function as a wiring member in the inverter circuit and are formed of, for example, a metal plate, a metal foil, or the like of copper, aluminum, or the like. The first conductor pattern 401 and the second conductor pattern 402 may be also referred to as conductor layers, conductor plates, conductive layers, or wiring patterns.

On the first conductor pattern 401, the first semiconductor element 5A bonded to the first conductor pattern 401 with a bonding material (not illustrated) is disposed. On the second conductor pattern 402, the second semiconductor element 5B bonded to the second conductor pattern 402 with a bonding material 22 is disposed. The first semiconductor element 5A and second semiconductor element 5B are bonded to the first conductor pattern 401 and the second conductor pattern 402 respectively with the conductive bonding material such as solder.

Each of the first semiconductor element 5A and the second semiconductor element 5B is formed of, for example, a reverse conducting (RC)-insulated gate bipolar transistor (IGBT) element obtained by integrating an IGBT element that is a switching element and a diode element such as a free wheeling diode (FWD) element or the like connected to the switching element in an inverse parallel manner. The switching element and the diode element in the semiconductor elements 5A and 5B are not limited to be formed on a Si substrate, and may be formed on a semiconductor substrate using a wide band gap semiconductor such as silicon carbide (SiC) or gallium nitride (GaN), for example. In each of this type of semiconductor elements 5A and 5B, a first main electrode (not illustrated) is provided on a bottom surface, and a second main electrode and a control electrode (gate electrode) (not illustrated) are provided on a top surface. That is, the first conductor pattern 401 is electrically connected to the first main electrode of the first semiconductor element 5A with a conductive bonding material, and the second conductor pattern 402 is electrically connected to the first main electrode of the second semiconductor element 5B with the conductive bonding material 22.

The second main electrode provided on the top surface of the first semiconductor element 5A is electrically connected to an output terminal 803 provided on the case 8 with the bonding wire 7A. The control electrode provided on the top surface of the first semiconductor element 5A is electrically connected to a first control terminal 804 provided on the case 8 with the bonding wire 7C. The first conductor pattern 401 electrically connected to the first main electrode provided on the bottom surface of the first semiconductor element 5A is electrically connected to a first input terminal (P terminal) 801 provided on the case 8 with the bonding wire 7B. That is, the first main electrode of the first semiconductor element 5A is electrically connected to the first input terminal 801 provided on the case 8, via the bonding material, the first conductor pattern 401, and the bonding wire 7B.

The second main electrode provided on the top surface of the second semiconductor element 5B is electrically connected to a second input terminal (N terminal) 802 provided on the case 8 with the bonding wire 7D. The control electrode provided on the top surface of the second semiconductor element 5B is electrically connected to a second control terminal 805 provided on the case 8 with the bonding wire 7F. The second conductor pattern 402 electrically connected to the first main electrode provided on the bottom surface of the second semiconductor element 5B is electrically connected to the output terminal 803 provided on the case 8 with the bonding wire 7E. That is, the first main electrode of the second semiconductor element 5B is electrically connected to the output terminal 803 provided on the case 8, via the bonding material 22, the second conductor pattern 402, and the bonding wire 7E.

The first input terminal 801, the second input terminal 802, the output terminal 803, the first control terminal 804, and the second control terminal 805 are integrally provided with an insulating member 800 of the case 8. The insulating member 800 has a top surface and a bottom surface opened, and has a hollow portion that can accommodate the wiring board 4, the semiconductor elements 5A and 5B, the bonding wires 7A to 7F, or the like arranged on the top surface of the heat dissipation base 3. The insulating member 800 is formed, for example, using an insulating resin material such as poly phenylene sulfide (PPS) or poly amide (PA). The first input terminal 801, the second input terminal 802, the output terminal 803, the first control terminal 804, and the second control terminal 805 are formed, for example, using a metal plate such as a copper plate and are integrated with the insulating member 800 through insert molding, for example.

Portions of the first input terminal 801, the second input terminal 802, and the output terminal 803 protruding from the top surface of the insulating member 800 are bent to extend along the top surface of the insulating member 800. An accommodation portion (not illustrated) that can accommodate a nut 15 in a direction in which an axial direction of a screw hole is set to be the vertical direction is provided in each of a region overlapping the first input terminal 801, a region overlapping the second input terminal 802, and a region overlapping the output terminal 803, in the top surface of the insulating member 800. In each of the first input terminal 801, the second input terminal 802, and the output terminal 803, a through-hole (not illustrated) that enables to screw a screw component such as a bolt into the nut 15 accommodated in the accommodation portion of the insulating member 800 is provided.

One end of each of the first input terminal 801, the second input terminal 802, the output terminal 803, the first control terminal 804, and the second control terminal 805 is exposed on an inner peripheral surface that defines the hollow portion in the insulating member 800. One ends of the bonding wires 7A to 7F are electrically connected to the portion of the corresponding terminal exposed on the inner peripheral surface of the insulating member 800.

The case 8 is attached to the heat dissipation base 3 by adhering the bottom surface of the insulating member 800 to the top surface of the heat dissipation base 3. An adhesive 16 that adheres the insulating member 800 and the heat dissipation base 3 may be an epoxy-based or silicone-based adhesive, for example. The wiring board 4, the semiconductor elements 5A and 5B, and the bonding wires 7A to 7F arranged on the top surface of the heat dissipation base 3 are positioned in a recessed space defined by the heat dissipation base 3 and the insulating member 800 of the case 8, and are sealed with the sealing material 9 added in the recessed space. The sealing material 9 may be an epoxy resin, silicone gel, or the like, for example.

As illustrated in FIG. 1, the heat dissipation base 3 has a substantially rectangular shape with rounded corners in plan view, and is a plate-shaped member in which through holes (not illustrated) through which the shafts of the screws 13 can be inserted are formed at the corners.

The heat dissipation base 3 is a member that functions as a heat conducting member that conducts heat generated by the semiconductor elements 5A and 5B to the cooler 10, and is formed of a metal plate such as a copper plate or an aluminum plate, for example. In the heat dissipation base 3, for example, the flat plate-shaped metal plate is warped through press working or the like so that the bottom surface 301 is formed into a convex curved surface. A corner on an outer peripheral side of the insulating member 800 of the case 8 is cut so as not to overlap the through hole of the heat dissipation base 3 in plan view (more specifically, the screws 13 can be screwed into screw holes of the fin 11).

As described above, the semiconductor module 2 described above with reference to FIGS. 1 to 3 forms the single-phase voltage type half-bridge inverter circuit (hereinafter, described as “half-bridge inverter circuit”) as illustrated in FIG. 4. The half-bridge inverter circuit includes a switching element 503 and a diode element 504 connected between a first input end IN (P) and an output end OUT and a switching element 505 and a diode element 506 connected between a second input end IN (N) and the output end OUT. Between the first input end IN (P) and the output end OUT may be referred to as an upper arm, and between the second input end IN (N) and the output end OUT may be referred to as a lower arm. In the semiconductor module 2 described above with reference to FIGS. 1 to 3, the switching element 503 and the diode element 504 in the upper arm are formed in the first semiconductor element 5A, and the switching element 505 and the diode element 506 in the lower arm are formed in the second semiconductor element 5B.

In a case where the switching elements 503 and 505 are IGBT elements, the first main electrode on the bottom surface side of the first semiconductor element 5A and the second semiconductor element 5B is referred to as a collector electrode, and the second main electrode on the top surface side thereof is referred to as an emitter electrode. The collector electrode of the switching element 503 of the upper arm is connected to the first input end IN (P) that may be the first input terminal 801, and the emitter electrode of the switching element 505 of the lower arm is connected to the second input end IN (N) that may be the second input terminal 802. The first input end IN (P) and the second input end IN (N) are respectively connected to a positive electrode and a negative electrode of a DC power supply. The emitter electrode of the switching element 503 of the upper arm and the collector electrode of the switching element 505 of the lower arm are connected to the output end OUT that may be the output terminal 803. Furthermore, a gate of the switching element 503 and a gate of the switching element 505 are connected to a control circuit (not illustrated), respectively via the first control terminal 804 and the second control terminal 805.

The half-bridge inverter circuit illustrated in FIG. 4 can convert a direct current between the first input end IN (P) and the second input end IN (N) into an alternating current and output the alternating current from the output end OUT, by a control signal applied to the gate of the switching element 503 of the upper arm and a control signal applied to the gate of the switching element 505 of the lower arm. Furthermore, the three half-bridge inverter circuits illustrated in FIG. 4 in parallel are connected between the first input end IN (P) and the second input end IN (N) to control the control signal to be applied to each circuit, so that a three-phase AC inverter circuit can be formed.

The semiconductor module 2 including the half-bridge inverter circuit described above with reference to FIG. 4 is not limited to have the configuration described above with reference to FIGS. 1 to 3. The switching elements 503 and 505 may include, for example, a power metal oxide semiconductor field effect transistor (MOSFET), a bipolar junction transistor (BJT), or the like. In a case where the switching element is a MOSFET element, the main electrode on the bottom surface side of the semiconductor elements 5A and 5B may be referred to as a drain electrode, and the main electrode on the top surface side may be referred to as a source electrode. Furthermore, the diode elements 504 and 506 may include, for example, a schottky barrier diode (SBD), a junction barrier schottky (JBS) diode, a merged PN schottky (MPS) diode, a PN diode, or the like. Furthermore, a substrate on which the switching elements 503 and 505 and the diode elements 504 and 506 are formed is not limited to a Si substrate, and may be, for example, a substrate using a wide band gap semiconductor such as silicon carbide (SiC) or gallium nitride (GaN).

Furthermore, in the semiconductor module 2, for example, the switching element 503 and the diode element 504 of the upper arm and the switching element 505 and the diode element 506 of the lower arm may be different semiconductor elements. For example, the switching element 503 and the diode element 504 of the upper arm are not limited to the single semiconductor element 5A (single semiconductor chip) in which they are formed on a single semiconductor substrate and may include one or more semiconductor elements (one or more semiconductor chips) on which the switching element 503 is formed and one or more semiconductor elements (one or more semiconductor chips) on which the diode element 504 is formed. The shape, number, placement, and the like of the semiconductor element can be changed as appropriate. A layout of a conductor pattern as the wiring member provided on the top surface side of the wiring board 4 is changed according to the type and shape of the semiconductor element to be mounted, the number of the semiconductor elements to be arranged, the placement of the semiconductor elements, and the like. Furthermore, some or all of the bonding wires 7A to 7F in the semiconductor module 2 described above may be replaced with leads that are formed by processing a metal plate such as a copper plate, for example.

Furthermore, the control electrodes provided on the top surfaces of the semiconductor elements 5A and 5B may include a gate electrode and an auxiliary electrode. For example, the auxiliary electrode may be an auxiliary emitter electrode or an auxiliary source electrode electrically connected to the main electrode on the top surface side and serving as a reference potential with respect to a gate potential. Furthermore, the auxiliary electrode may be a temperature sensing electrode that is electrically connected to a temperature sensing unit that may be included in an inverter device or the like including the semiconductor module 2 and measures temperatures of the semiconductor elements 5A and 5B. These electrodes (main electrode and control electrode including gate electrode and auxiliary electrode) formed on the top surfaces of the semiconductor elements 5A and 5B may be collectively referred to as top surface electrodes.

A circuit configuration of the semiconductor module 2 is not limited to the half-bridge inverter circuit described above with reference to FIG. 4. The inverter circuit of the semiconductor module 2 may be, for example, a single-phase full-bridge inverter circuit. Furthermore, the inverter circuit in the single semiconductor module 2 is not limited to a single phase and may be, for example, the three-phase AC inverter circuit as described above.

The cooler 10 attached to the semiconductor module 2 described above with reference to FIGS. 1 to 3 includes the fin 11 and the water jacket 12. The fin 11 includes a base 1101 having the top surface 1110 on which the semiconductor module 2 is attached, and a plurality of fin portions 1102 extending downward from a bottom surface of the base 1101. When being attached to the fin 11, the water jacket 12 has a shape for defining a flow path of a refrigerant in which the fin portion 1102 is disposed. The energy conversion device 1 according to the present embodiment conducts a part of the heat generated by the semiconductor elements 5A and 5B during an operation of the semiconductor module 2 to the cooler 10 via the wiring board 4 and the heat dissipation base 3 and dissipates the heat. In this type of energy conversion device 1, adhesion between the heat dissipation base 3 and the fin 11 is improved with the heat conductive material 14 such as thermal grease, which makes it possible to efficiently conduct the heat from the heat dissipation base 3 to the cooler 10 (fin 11).

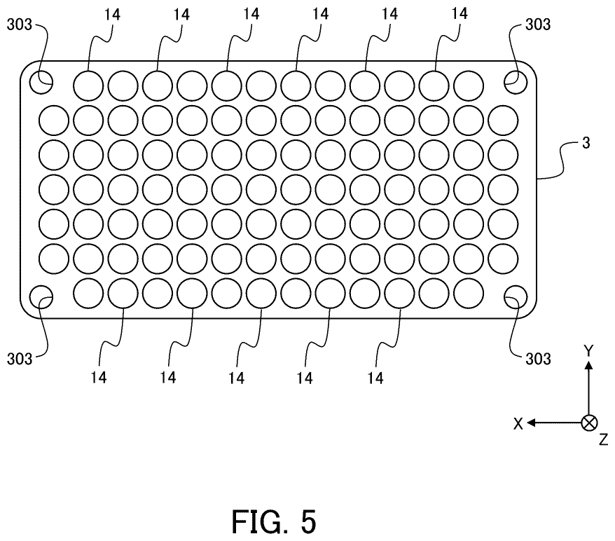

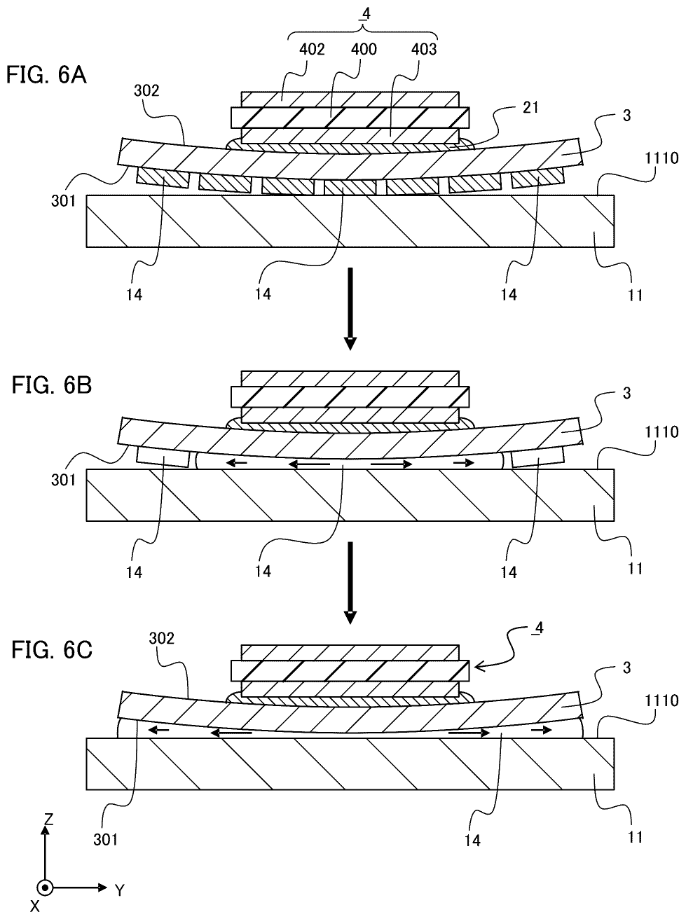

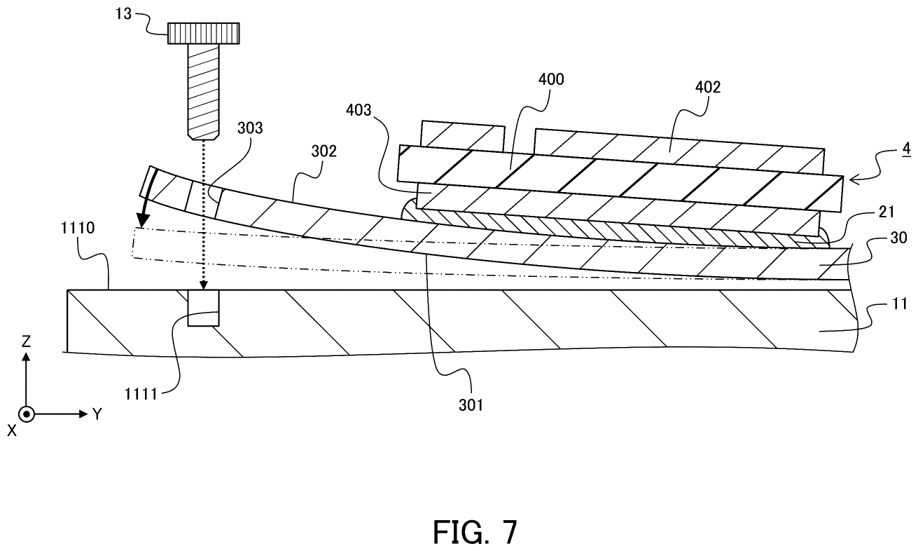

FIG. 5 is a bottom view illustrating an example of a coating pattern of a heat conductive material when a heat dissipation base is attached to a cooler. FIG. 6 is a diagram illustrating how a heat conductive material spreads when a heat dissipation base is attached to a cooler. FIG. 7 is a diagram illustrating an example of a problem that occurs when a heat dissipation base is attached to a cooler. Note that, in FIGS. 6 and 7, the fin portion 1102 of the fin 11 is omitted.

In a case where the adhesion between the heat dissipation base 3 and the fin 11 is improved with the heat conductive material 14 such as thermal grease, for example, as illustrated in FIGS. 5 and A of 6, the plurality of heat conductive materials 14 is arranged on the bottom surface 301 of the heat dissipation base 3 in a predetermined pattern. The heat dissipation base 3 has a rectangular shape with rounded corners in plan view, and a through hole 303 in which the screw 13 is inserted is formed at the corner. Furthermore, for example, the heat dissipation base 3 has a shape in which the flat plate-like metal plate is warped so that the bottom surface 301 is formed into a convex curved surface through press working or the like. The bottom surface 301 of the heat dissipation base 3 illustrated in A to C of FIG. 6 is a curved surface in which a center portion of the bottom surface 301 is a top portion in plan view and a change in a relative position of each point of the bottom surface 301 with respect to the center portion in the Z direction is represented by a downward convex curve.

The plurality of heat conductive materials 14 is arranged on the bottom surface 301 of the heat dissipation base 3, except for a portion around the through hole 303. An arrangement pattern of the plurality of heat conductive materials 14 is not limited to a pattern in which same shapes with the same dimensions are aligned and arranged as illustrated in FIG. 5. The plurality of heat conductive materials 14 arranged on the bottom surface 301 of the heat dissipation base 3 may have a plurality of shapes or may have the same shape and a plurality of dimensions, for example. For example, the arrangement pattern of the plurality of heat conductive materials 14 may change in accordance with a distance from the center of the bottom surface 301 of the heat dissipation base 3 in plan view.

When the bottom surface 301 of the heat dissipation base 3 is arranged on the fin 11 to face the top surface 1110 of the fin 11, as illustrated in A of FIG. 6, the heat conductive materials 14 arranged at the center of the bottom surface 301 and the vicinity thereof first have contact with the top surface 1110 of the fin 11. Thereafter, for example, when the heat dissipation base 3 is pressed against the top surface 1110 of the fin 11, as illustrated in B and C of FIG. 6, the heat conductive material 14 having contact with the fin 11 is integrated between the bottom surface 301 of the heat dissipation base 3 and the top surface 1110 of the fin 11 while extending radially outward from the center of the bottom surface 301. At this time, when the bottom surface 301 of the heat dissipation base 3 is formed to be a convex curved surface, the heat conductive material 14 easily extends radially outward from the center of the bottom surface 301 of the heat dissipation base 3, and a gap is hardly generated in the integrated heat conductive material 14.

However, when the heat dissipation base 3 is attached to the fin 11 of the cooler 10, as illustrated in A to C of FIG. 6, the wiring board 4 is bonded to a top surface 302 of the heat dissipation base 3. Furthermore, when the heat dissipation base 3 is attached to the fin 11 of the cooler 10, after the heat conductive material 14 is extended between the heat dissipation base 3 and the fin 11, and the heat dissipation base 3 is fixed to the fin 11 using the screw 13.

FIG. 7 schematically illustrates deformation of a heat dissipation base 30, which is used in a conventional semiconductor device (semiconductor module), occurring when the heat dissipation base 30 is attached to the fin 11 of the cooler 10. In the conventional heat dissipation base 30, when the bottom surface 301 faces downward, for example, the shape of the bottom surface 301 viewed on a straight line in a diagonal direction passing through the through hole 303 for screwing is represented by a downward convex curve.

In a case where the through hole 303 for screwing is positioned at the corner of the bottom surface 301 of the heat dissipation base 30, when the screw 13 that is inserted into the through hole 303 is screwed into a screw hole 1111 in the top surface 1110 of the fin 11, as illustrated in FIG. 7, the heat dissipation base 30 is deformed from the convex curved surface of the bottom surface 301 (curved surface indicated by a solid curve) to a nearly-flat curved surface with a small curvature (curved surface indicated by an alternate long and two short dashed curve). That is, when the heat dissipation base 30 is attached to the fin 11 with the screw 13, the heat dissipation base 30 is deformed in a direction in which warpage becomes smaller than that before the attachment. When the deformation of the heat dissipation base 30 occurs in the direction in which the warpage becomes smaller, a deformation stress is applied to the wiring board 4 bonded to the top surface 302 of the heat dissipation base 30, and this causes damage to the wiring board 4, for example, the insulating substrate 400 is cracked or the conductor patterns 401 to 403 are delaminated from the insulating substrate 400. Such damage to the wiring board 4 easily occurs in a case where an area of the bottom surface 301 of the heat dissipation base 30 is large, the wiring board 4 is disposed to the vicinity of the through hole 303, and the through hole 303 in which the screw 13 is inserted is formed at the corner of the bottom surface 301.

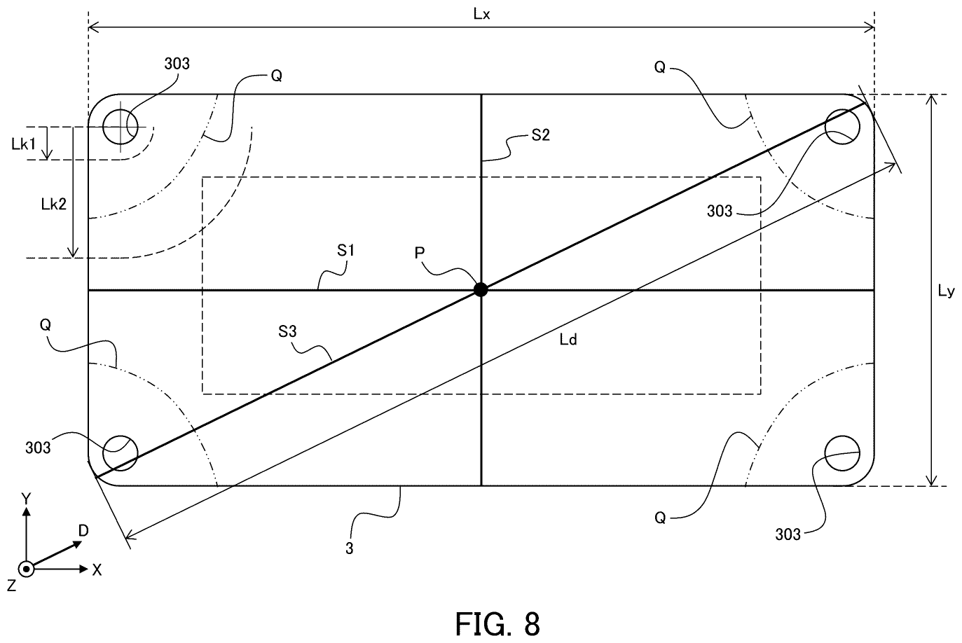

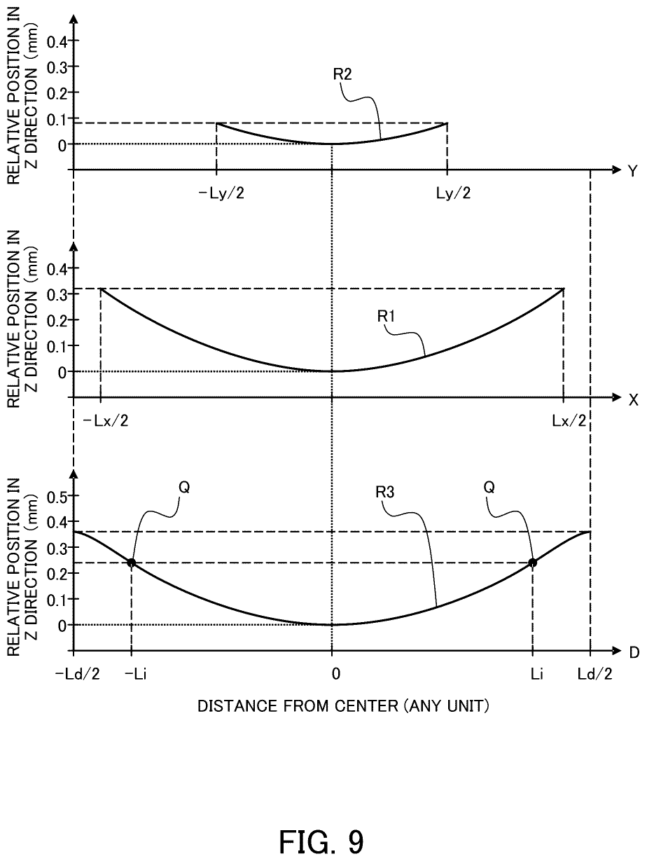

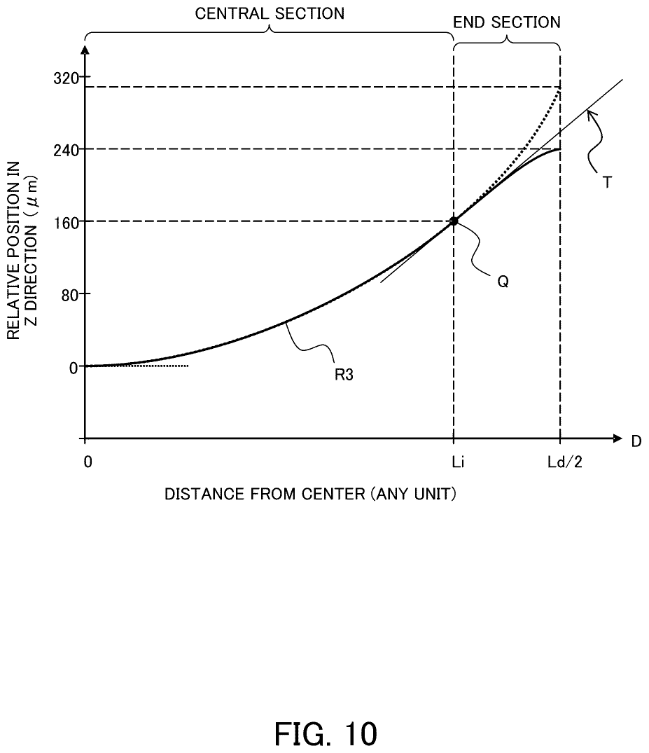

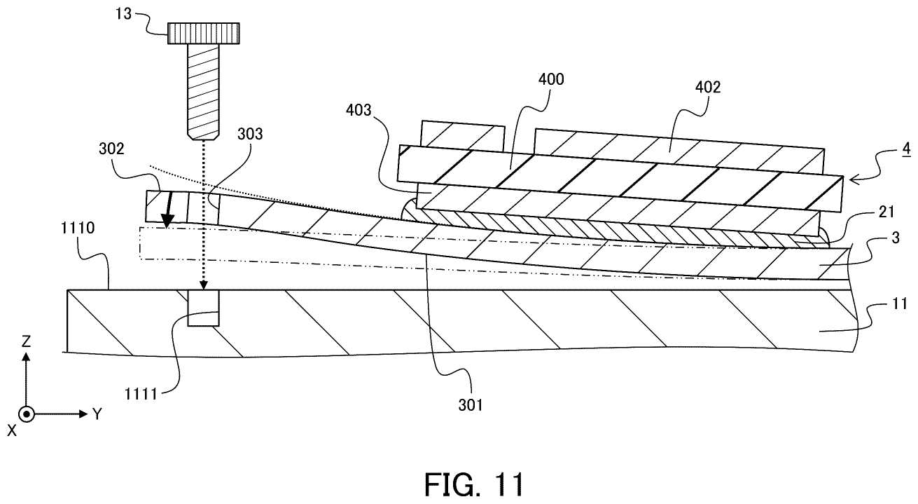

FIG. 8 is a top view illustrating an example of a shape of a heat dissipation base according to the embodiment. FIG. 9 is a graph illustrating the tendency of warpage in three directions in the heat dissipation base illustrated in FIG. 8. FIG. 10 is a graph illustrating a specific example of warpage in the diagonal direction in the heat dissipation base illustrated in FIG. 8. FIG. 11 is a diagram illustrating deformation of the heat dissipation base illustrated in FIG. 8 when the heat dissipation base is attached to the cooler.

FIG. 8 is a diagram illustrating a definition of a parameter used to describe the shape of the heat dissipation base 3 according to the present embodiment. The shape of the convex curved surface of the bottom surface 301 in the heat dissipation base 3 according to the present embodiment is described by using a curve indicating the shape of the bottom surface 301 viewed on a straight line S1 in the longitudinal direction (X direction) passing through the center P of the bottom surface 301 in plan view, a curve indicating the shape of the bottom surface 301 viewed on a straight line S2 in the lateral direction (Y direction), and a curve indicating the shape of the bottom surface 301 viewed on a straight line S3 in the diagonal direction (D direction). The heat dissipation base 3 illustrated in FIG. 8 has a longitudinal dimension Lx (mm), a lateral dimension Ly (mm), and a diagonal dimension Ld (mm). For simplicity of explanation, it is assumed that the bottom surface 301 of the heat dissipation base 3 is a convex curved surface having the center P as an apex in plan view.

In the graph of FIG. 9, a curve R1 indicates the shape of the bottom surface 301 viewed on the straight line S1 in the longitudinal direction (X direction) of the heat dissipation base 3 exemplified in FIG. 8, and a curve R2 indicates the shape of the bottom surface 301 viewed on the straight line S2 in the lateral direction (Y direction) of the heat dissipation base 3 exemplified in FIG. 8. In the graph of FIG. 9, a curve R3 indicates the shape of the bottom surface 301 viewed on the straight line S3 in the diagonal direction (D direction) of the heat dissipation base 3 exemplified in FIG. 8. The shape of the bottom surface 301 indicated by the straight line S3 includes a part to be an open end on the bottom surface 301 side of the through hole 303. In the graph of FIG. 9, the horizontal axis represents the distance from the center P of the bottom surface 301. The distance of the portion located on the positive side with respect to the center P in each of the X direction, the Y direction, and the D direction is indicated by a positive value, and the distance of the portion located on the negative side with respect to the center P in each of the X direction, the Y direction, and the D direction is indicated by a negative value. In the graph of FIG. 9, the vertical axis represents the relative position in the Z direction of each point with respect to the position in the Z direction of the center P when the bottom surface 301 of the heat dissipation base 3 faces downward (negative side in the Z direction).

In the bottom surface 301 of the heat dissipation base 3 of the present embodiment, the relative position in the Z direction of each point on the straight line S1 in the longitudinal direction (X direction) passing through the center P is represented by a downward convex curve as a whole, as represented by the curve R1. On the straight line S1, the relative position in the Z direction in the direction from the end point (end) of the straight line S1 to the center P including the end point and the relative position in the Z direction in the direction from the center P to the end point including the center P both change as indicated by downward convex curves. Similarly, in the bottom surface 301 of the heat dissipation base 3 of the present embodiment, the relative position in the Z direction of each point on the straight line S2 in the lateral direction (Y direction) passing through the center P is represented by a downward convex curve as a whole, as represented by the curve R2. On the straight line S2, the relative position in the Z direction in the direction from the end point (end) of the straight line S2 to the center P including the end point and the relative position in the Z direction in the direction from the center P to the end point including the center P both change as indicated by downward convex curves.

On the other hand, the bottom surface 301 of the heat dissipation base 3 of the present embodiment has a section in which the relative position in the Z direction of each point on the straight line S3 in the diagonal direction (D direction) passing through the center P changes as indicated by a downward convex curve and a section in which the relative position changes as indicated by an upward convex curve, as represented by the curve R3. On the straight line S3, the relative position in the Z direction in the direction from the end point (end) of the straight line S3 to the center P including the end point changes as indicated by an upward convex curve, and the relative position in the Z direction in the direction from the center P to the end point including the center P changes as indicated by a downward convex curve. Specifically, a section in which the distance Lp from the center is Li>Lp>-Li has a change as indicated by a downward convex curve, and a section in which the distance Lp from the center is Lp>Li has a change as indicated by an upward convex curve. That is, the curve R3 has inflection points Q at distances of -Li and Li from the center P.

The distances -Li and Li associated with the positions of the inflection points Q are set to range, for example, between a minimum value Lk1 and a maximum value Lk2 of the distance from the center of the through hole 303 for screwing formed at the corner of the heat dissipation base 3. The minimum value Lk1 and the maximum value Lk2 of the distance are set based on, for example, a dimension Lx in the longitudinal direction and a dimension Ly in the lateral direction of the heat dissipation base 3, the hole diameter of the through hole 303 for screwing, and the like. In a case where the dimension Lx in the longitudinal direction and the dimension Ly in the lateral direction of the heat dissipation base 3 are about 120 mm and about 60 mm respectively and where the hole diameter of the through hole 303 for screwing is about 5 mm, the minimum value Lk1 and the maximum value Lk2 of the distance can be set to, for example, 5 mm and 20 mm respectively.

In the curve R3 illustrated in FIG. 9, the downward convex curve and the upward convex curve with the inflection point Q as the boundary are desirably set such that a tangent of the upward convex curve at the position of the inflection point Q coincides with a tangent T of the downward convex curve, for example, as illustrated in FIG. 10. If this is achieved, the relative position in the Z direction at each point of an end section from the end point to the closest inflection point Q on the straight line S3 in the diagonal direction can be made smaller than the relative position (the relative position indicated by a dotted line in FIG. 10) for a case where the change in the relative position in the Z direction in a central section between the two inflection points Q is extended to the end section.

In a case where the change in the convex curved surface in the diagonal direction (D direction) of the heat dissipation base 3 satisfies the above-described condition (the condition for the curve R3), the distance Li from the center is about 48 mm, and the relative position in the Z direction at the position corresponding to the distance Li is 160 μm, the relative position in the Z direction at the end in the diagonal direction can be, for example, about 240 μm. On the other hand, in a case where the change in the relative position in the Z direction in the diagonal direction is only a change represented by a downward convex curve without the inflection point Q, which is similar to the change in the longitudinal direction and the change in the lateral direction, the change in the relative position in the Z direction in the end section is a change indicated by a dotted line in FIG. 10. In this case, the relative position in the Z direction at the end in the diagonal direction is, for example, about 310 μm.

As described above, the convex curved surface of the bottom surface 301 of the heat dissipation base 3 is formed into the shape described above with reference to FIGS. 8 to 10. This reduces the amount of deformation, which occurs when the heat dissipation base 3 is attached to the cooler 10 (fin 11), in the direction in which the warpage of the heat dissipation base 3 becomes smaller.

That is, when the heat dissipation base 3 of the present embodiment is attached to the fin 11 of the cooler 10, as illustrated in FIG. 11, the distance in the Z direction from the corner of the heat dissipation base 3 to the top surface 1110 of the fin 11 can be shortened as compared with the case of the heat dissipation base 30 in which the shape of the curved surface is represented by the downward convex curve up to the end indicated by the dotted line (see FIG. 7). Therefore, the amount of deformation of the heat dissipation base 3 generated when the screw 13 is inserted into the through hole 303 of the heat dissipation base 3 and screwed into the screw hole 1111 of the fin 11 can be made smaller than the amount of deformation of the conventional heat dissipation base 30 described above with reference to FIG. 7. Therefore, the use of the heat dissipation base 3 of the present embodiment reduces the deformation stress on the wiring board 4 due to the deformation of the heat dissipation base 3 at the time of attaching the heat dissipation base 3 to the fin 11, which prevents damage to the wiring board 4 due to the deformation stress.

In addition, as described above with reference to FIG. 10, in the heat dissipation base 3 of the present embodiment, the bottom surface 301 can smoothly change from the downward convex curved surface to the upward convex curved surface at the inflection point Q that occurs when viewed on the straight line S3 in the diagonal direction. As described above, the curved surface of the bottom surface 301 is smoothly changed at the inflection point Q. Thereby, stress concentration is less likely to occur at the inflection point Q and the deformation stress on the wiring board 4 due to the deformation of the heat dissipation base 3 is easily reduced as compared with, for example, a case where bending processing is performed in which a tangent line discontinuously changes around the inflection point Q.

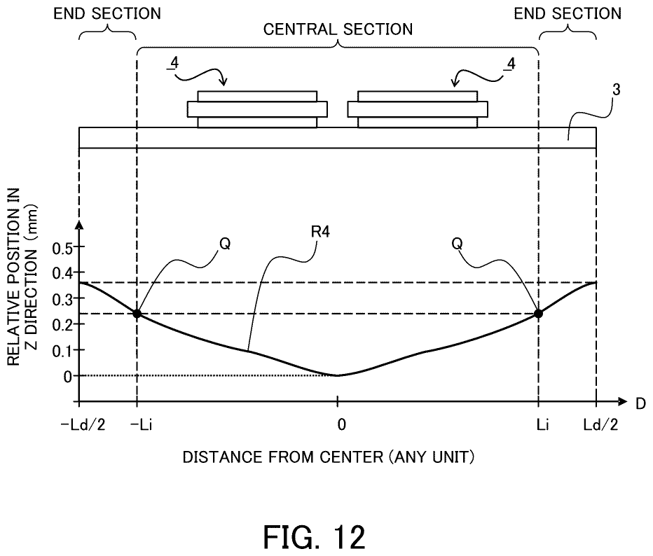

FIG. 12 is a supplementary diagram for a shape of a convex curved surface in the heat dissipation base according to the embodiment.

As an example of the shape of the bottom surface 301 on the straight line S3 in the diagonal direction in the heat dissipation base 3 of the present embodiment, the curves R3 in FIGS. 9 and 10 indicate the shape of the bottom surface 301 before the wiring board 4 is bonded to the top surface 302 of the heat dissipation base 3. In a case where the wiring board 4 is bonded to the top surface of the heat dissipation base 3 of the present embodiment described above, the relative position in the Z direction at each point on the straight line S3 in the diagonal direction may change, for example, as indicated by a curve R4 illustrated in FIG. 12. Similarly to the curve R3, the curve R4 has a section in which the relative position in the Z direction changes as represented by a downward convex curve and a section in which the relative position in the Z direction changes as represented by an upward convex curve. The curve R4 has two end sections that are divided at the positions corresponding to the distances -Li and Li, and have a change in which the relative position in the Z direction in the direction from the end point to the center P including the end point of the curve R4 is represented only by an upward convex curve, and a central section located between the two end sections. The change in the relative position in the Z direction in the central section of the curve R4 is different from the change in the central section of the curve R3, and includes a section represented by a downward convex curve and a section represented by an upward convex curve.

Although not described with reference to the drawings, in a case where the wiring board 4 is bonded to the heat dissipation base 3, the relative position in the Z direction at each point on the straight line in the longitudinal direction passing through the center of the bottom surface 301 and the relative position in the Z direction at each point on the straight line in the lateral direction may also be represented by a curve having a section represented by a downward convex curve and a section represented by an upward convex curve, such as the central section of the curve R4.

However, also in a case where the central section includes a section represented by a downward convex curve and a section represented by an upward convex curve, the change in the relative position in the Z direction in the direction from the end point (end) to the center including the end point is the change described with reference to FIGS. 9 and 10. Therefore, even when the central section includes the section represented by a downward convex curve and the section represented by an upward convex curve, the amount of deformation generated when the heat dissipation base 3 is attached to the cooler 10 (fin 11) can be reduced.

As described above, in the heat dissipation base 3 according to the present embodiment, the bottom surface 301 that is to face the fin 11 of the cooler 10 is a convex curved surface, the shape of the bottom surface 301 on the straight line S1 in the longitudinal direction passing through the center P of the bottom surface 301 and the shape of the bottom surface on the straight line S2 in the lateral direction include an end, the change in the shape in the direction from the end to the center P is represented by a downward convex curve, the shape of the bottom surface 301 on the straight line S3 in the diagonal direction includes an end, and the change in the shape in the direction from the end to the center P is represented by an upward convex curve. Therefore, as compared with the heat dissipation base 30 (see FIG. 7) in which the change in the shape in the direction from the end to the center P including the end is represented by a downward convex curve, in the heat dissipation base 3 according to the present embodiment, in the shape of the bottom surface 301 on the straight line S3 in the diagonal direction, the amount of deformation at the time of attaching the heat dissipation base 3 to the fin 11 can be reduced, and the deformation stress on the wiring board 4 bonded to the top surface of the heat dissipation base 3 can be reduced. Therefore, in the energy conversion device 1 using the heat dissipation base 3 according to the present embodiment, damage to the wiring board 4 due to a deformation stress can be prevented, and failure in the energy conversion device 1 (semiconductor module 2) can be prevented.

The embodiment of the heat dissipation base 3 and the energy conversion device 1 according to the present invention are not limited to the above embodiments, and may be variously modified, replaced, and deformed without departing from the spirit of the technical idea. Further, when the technical idea may be implemented in another method by the progress of the technology or another derived technology, the technical idea may be carried out by using the method thereof. Therefore, the claims cover all implementations that may be included within the scope of the technical idea.

For example, in the heat dissipation base 3 according to the above embodiment, a flat-plate-like base plate is warped through press working or the like to form the bottom surface 301 into a convex curved surface, and the top surface 302 to which the wiring board 4 is bonded is formed to have a recessed curved surface. However, the shape of the heat dissipation base 3 according to the present invention is not limited to such a shape. In the heat dissipation base 3 according to the present invention, for example, the bottom surface 301 that is to face the fin 11 of the cooler 10 may be a convex curved surface, and the top surface 302 to which the wiring board 4 is bonded may be a flat surface. Furthermore, a position of the apex when the bottom surface 301 of the heat dissipation base 3 is the convex curved surface is not limited to be the center of the bottom surface 301 in plan view and may be a position away from the center. In addition, the number of wiring boards 4 bonded to one heat dissipation base 3 may be two or more, and the inflection point Q in the heat dissipation base 3 is desirably present outside the region where the wiring board 4 is bonded in plan view from the viewpoint of preventing the wiring board 4 from being broken starting from the inflection point Q at the time of screwing, for example. However, for example, as illustrated in FIG. 8, a part of the inflection points Q distributed in a curve on the bottom surface 301 of the heat dissipation base 3 may be present inside the region where the wiring board 4 is bonded in the heat dissipation base 3. Moreover, the through hole 303 for screwing of the heat dissipation base 3 may be formed, for example, in an intermediate portion of an end side in the longitudinal direction, in addition to the corner on the bottom surface 301. Furthermore, the shape of the heat dissipation base 3 in plan view is not limited to a substantially rectangular planar shape of which a length of a side extending in the X direction is different from a length of a side extending in the Y direction, as described above with reference to FIG. 8 and may be a substantially square planar shape of which a length of a side extending in the X direction and a length of a side extending in the Y direction are substantially the same.

Hereinafter, feature points in the above-described embodiment will be summarized.

The heat dissipation base according to the embodiment described above is a heat dissipation base including a first surface to which a wiring board is to be bonded; and a second surface which is opposite to the first surface and is to face a cooler, in which the second surface of the heat dissipation base is a convex curved surface and has a substantially rectangular shape in plan view having a side extending in a first direction and a side extending in a second direction, and when the second surface faces downward, in each of a first curve representing a shape of the second surface on a first straight line passing through a center of the second surface and extending in the first direction, and a second curve representing a shape of the second surface on a second straight line passing through the center of the second surface and extending in the second direction, a change in a shape in a direction from an end to the center including the end is represented by a downward convex curve, and in a third curve representing a shape of the second surface on a straight line in a diagonal direction of the heat dissipation base, a change in a shape in a direction from an end to the center including the end is represented by an upward convex curve, and a change in a shape in a direction from the center to the end including the center is represented by a downward convex curve.

In the heat dissipation base according to the above embodiment, a through hole through which a male screw for attaching the heat dissipation base to the cooler is insertable is formed at a position corresponding to a corner of the second surface in plan view.

In the heat dissipation base according to the above embodiment, the third curve representing the shape of the second surface on the straight line in the diagonal direction has an inflection point at a position closer to the center than the through hole, and a section between the end and the inflection point on the third curve is an upward convex curve.

In the heat dissipation base according to the above embodiment, the inflection point is present outside a region in which the wiring board is bonded.

In the heat dissipation base according to the above embodiment, the inflection point is located within a range in which a distance from a center of the through hole is 5 mm or more and 20 mm or less.

In the heat dissipation base according to the above embodiment, the first surface is a concave curved surface corresponding to the convex curved surface of the second surface.

In the heat dissipation base according to the above embodiment, the third curve representing the shape of the second surface on the straight line in the diagonal direction includes two end sections in which a change in a shape in a direction from the end to the center including the end is represented by the upward convex curve and a central section located between the two end sections, and has a partial section represented by an upward convex curve in the central section.

In the heat dissipation base according to the above embodiment, a length of the side extending in the first direction is different from a length of the side extending in the second direction.

The semiconductor module according to the embodiment includes the heat dissipation base according to the embodiment, a wiring board bonded to the first surface of the heat dissipation base, and a semiconductor element disposed on a top surface of the wiring board.

The energy conversion device according to the above embodiment includes the semiconductor module according to the above embodiment, the cooler that is disposed to face the second surface of the heat dissipation base and is attached to the heat dissipation base, and a heat conductive material added between the heat dissipation base and the cooler.

### INDUSTRIAL APPLICABILITY

As described above, the present invention has an effect of preventing a wiring board from being damaged due to deformation of a heat dissipation base to which the wiring board is bonded when the heat dissipation base is attached to a cooler, and in particular, is useful for an industrial or electrical inverter device.

The present application is based on Japanese Patent Application No. 2023-038214 filed on Mar. 13, 2023. All the contents are included herein.

### REFERENCE SIGNS LIST

1 Energy conversion device
2 Semiconductor module
3 Heat dissipation base
301 Bottom surface
302 Top surface
303 Through hole
4 Wiring board
400 Insulating substrate
401, 402, 403 Conductor pattern
5A, 5B Semiconductor element
7A to 7F Bonding wire
8 Case
800 Insulating member
801, 802 Input terminal
803 Output terminal
804, 805 Control terminal
9 Sealing material
10 Cooler
11 Fin
1110 Top surface
1111 Screw hole
12 Water jacket
13 Screw
14 Heat conductive material
15 Nut
16 Adhesive

1. A heat dissipation base, comprising:
a first surface configured to have a wiring board bonded thereto; and
a second surface that is a convex curved surface overall and has a substantially rectangular shape, which has two neighboring sides extending respectively in a first direction and a second direction, in a plan view of the heat dissipation base, wherein
the second surface is opposite to the first surface, and is so shaped that, when the second surface faces downward,
in a first cross-sectional view of the heat dissipation base along a first straight line passing through a center of the second surface and extending in the first direction, and a second cross-sectional view thereof along a second straight line passing through the center of the second surface and extending in the second direction, the second surface forms a first curve and a second curve, which are a first downward convex curve and a second downward convex curve, respectively, and
in a third cross-sectional view of the heat dissipation base along a third straight line passing through the center of the second surface and extending in a diagonal direction of the substantially rectangular shape, the second surface forms a third curve, the third curve having an inflection point, a first part of the third curve further outward than the infection point forming a first upward convex curve, and a second part of the third curve further inward than the infection point forming a third downward convex curve.

2. The heat dissipation base according to claim 1, wherein
the second surface has a through hole formed at a corner thereof in the plan view, so as to allow a male screw to be inserted therethrough for attaching the heat dissipation base to a cooler.

3. The heat dissipation base according to claim 2, wherein the inflection point is closer to the center of the second surface than to the through hole.

4. The heat dissipation base according to claim 3, wherein
the wiring board is bonded to a bonding region of the first surface, and
in the plan view, the inflection point is outside the bonding region.

5. The heat dissipation base according to claim 3, wherein a distance from the inflection point and a center of the through hole is in a range of 5 mm to 20 mm.

6. The heat dissipation base according to claim 1, wherein the first surface is a concave curved surface corresponding to the convex curved surface of the second surface.

7. The heat dissipation base according to claim 1, wherein
the inflection point of the third curve is an outermost inflection point,
the third curve further has another inflection point that is adjacent to, and further inward than, the outermost inflection point,
the second part is between the outermost infection point and the another infection point, and
the third curve further includes a third part that is further inward than the another inflection point and that forms a second upward convex curve.

8. The heat dissipation base according to claim 1, wherein lengths of the two neighboring sides of the substantially rectangular shape are different from each other.

9. A semiconductor module, comprising:
the heat dissipation base according to claim 1;
the wiring board bonded to the first surface of the heat dissipation base; and
a semiconductor element disposed on a top surface of the wiring board.

10. An energy conversion device, comprising:
the semiconductor module according to claim 9;
a cooler attached to the heat dissipation base and facing the second surface of the heat dissipation base; and
a heat conductive material provided between the heat dissipation base and the cooler.
